(19) United States
(12) Patent Application Publication
(10) Pub. No.: US 2004/0140490 A1
(43) Pub. Date: Jul. 22, 2004

(54) Hillock-free gate layer and method of manufacturing the same

(76) Inventor: Cheng-Chi Wang, Yungkang City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/676,555

(22) Filed: Oct. 1, 2003

(30) Foreign Application Priority Data
Jan. 16, 2003 (TW) 92100927

(51) Int. Cl. H01L 29/76; H01L 31/062; H01L 23/48; H01L 21/44

(52) U.S. Cl. 257/288; 257/765; 438/592; 438/688

(57) ABSTRACT

A hillock-free gate layer and method of manufacturing the same is disclosed. One or more pure aluminum layers are formed under high pressure and low sputtering power. An aluminum layer containing nitrogen is then formed on the pure aluminum layers to prevent the formation of hillocks and to reduce manufacturing costs.

This application claims the benefit of Taiwan application Serial No. 92100927, filed Jan. 16, 2003.

### BACKGROUND OF THE INVENTION

1. Field of the Invention

The invention relates in general to a conducting layer of aluminum, and more particularly to a hillock-free gate layer and method of manufacturing the same.

2. Description of the Related Art

In semiconductor manufacturing process, either molybdenum (Mo) or chromium (Cr) is usually selected to make a gate layer. However, using expensive molybdenum or chromium will increase the cost of the process. Aluminum, the most plentiful mineral metal on earth, is cheap, easily accessible, and is usually used to make metal layers. However, when aluminum is used to make the gate layer, it gives rise to an issue that hillocks are generated on the surface of the gate layer.

The advantages of aluminum when it is used in semiconductor manufacturing process are that aluminum has a low resistance, good adhesion to the substrate, and better etching characteristics during the etching process. However, aluminum has a lower melting point than other metals, and this is a disadvantage when it is used to make a gate layer. Referring to FIG. 1A, a schematic view of metal deposited on a glass substrate is shown. First, a metal is deposited on a glass substrate 102 at a lower temperature of about 150° C. As a result, some crystal particles 104 are formed on the substrate 102, and there are grain boundaries 106 between these crystal particles 104. Although the real crystal particles will not be regular as shown in FIG. 1A, regular crystal particles 104 are simply used as an example in the following illustration. An annealing process is subsequently conducted. The crystal particles 104 vibrate more frequently when they are heated to a high temperature. Therefore, atoms in crystal particles 104 will be rearranged, and crystal particles 104 will be recrystallized due to the absence of crystal defects. As a result, the inner stress to crystal particles 104 will be greatly reduced as the density of crystal defects is lowered. If the temperature of the annealing process is increased continuously, the crystal particles 104 formed during the recrystalline stage will have enough energy to overcome the surface energy between the two crystal particles 104 Accordingly, larger crystal particles will be formed when such grain boundaries 106 between crystal particles 104 disappear, thereby further lowering the inner stress to the crystal particles 104.

A problem with hillocks mentioned above occurs as aluminum is used to make the gate layer. Referring to FIG. 1B, a schematic view of an aluminum layer on a glass substrate after annealing is shown. The high temperature of the annealing process causes the aluminum crystal particles 104 and the glass substrate 102 to expand. The thermal expansion coefficient of aluminum is greater than that of the glass substrate, so that a great compressive stress is generated in the aluminum crystal particles 104, which forces aluminum atoms on the glass substrate 102 to grow along the crystal boundaries 106, leading hillocks 110 on the aluminum layer. The hillocks 110 generated on the metal layers will contact the following deposited metal layer, which causes short circuits of the aluminum layer 104 and following metal layer and result in severe damage.

As indicated above, an important industry research goal is to find a way to reduce costs by using aluminum during the semiconductor manufacturing process or gate-layer manufacturing process of liquid crystal displays without at the same time creating problems with hillocks.

### SUMMARY OF THE INVENTION

It is therefore an objective of the invention to provide a hillock-free gate layer and method of manufacturing the same. One or more aluminum layers, formed under high pressure and low sputtering power conditions, are covered with an aluminum layer containing nitrogen to prevent the formation of hillocks and to lower production costs.

The invention achieves the above-identified objectives by providing a hillock-free gate layer. At least two aluminum layers are formed on a substrate. The gate layer includes a pure aluminum layer formed on the substrate and an aluminum layer containing nitrogen formed on the pure aluminum layer. The upper aluminum layer containing nitrogen can prevent the lower pure aluminum layer from generating hillocks.

The invention achieves the above-identified objectives by providing a method of manufacturing a hillock-free gate layer that prevents the aluminum layer from generating hillocks. The gate layer, located on a substrate, includes at least two aluminum layers. The method includes the following steps: of under a first pressure and a first sputtering power, a pure aluminum layer is formed on the substrate, where the first pressure is about 0.5 Pa to 4 Pa, and the first sputtering power is about 0.1 w/cm² to 10 w/cm²; and under a second pressure and a second sputtering power, an aluminum layer containing nitrogen is formed on the pure aluminum layer, where the thickness of the aluminum layer containing nitrogen is about 100 Å to 1000 Å.

Other objectives, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A (prior art) is a schematic view of metal deposited on a glass substrate;

FIG. 1B (prior art) is a schematic view of an aluminum layer on a glass substrate after annealing;

FIG. 2 is a schematic view of two aluminum layers formed on a substrate according to a first preferred embodiment of the invention; and

FIG. 3 is a schematic view of three aluminum layers formed on a substrate according to a second preferred embodiment of the invention.

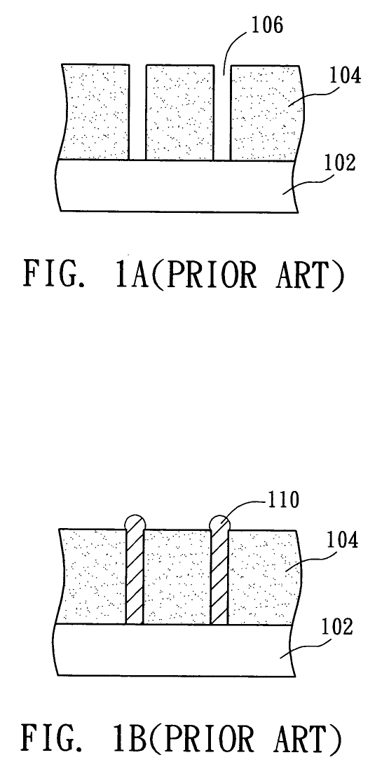

### DETAILED DESCRIPTION OF THE INVENTION

The feature of the invention is that an aluminum layer containing nitrogen is formed on one or more pure aluminum layers to prevent the hillock surface from forming. The pure aluminum layer is formed under the conditions of high pressure and low sputtering power.

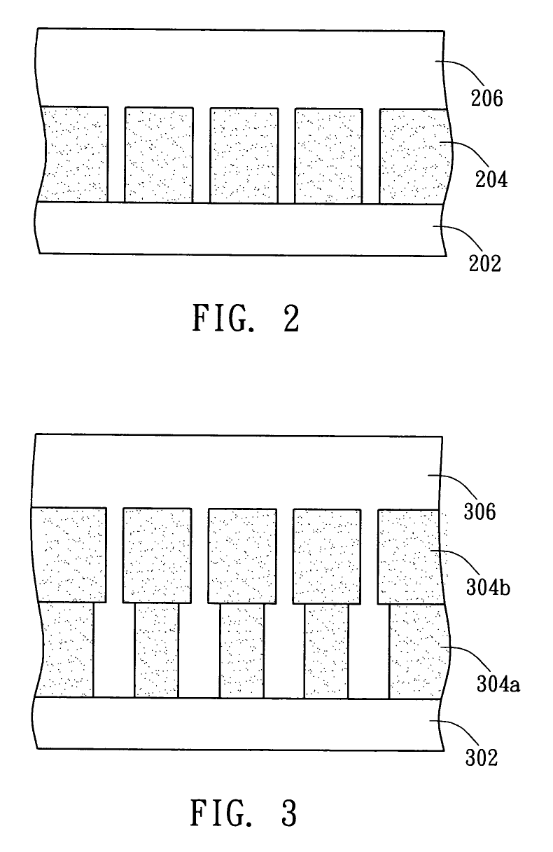

Referring to FIG. 2, a schematic view of two aluminum layers formed on a substrate according to a first preferred embodiment of the invention is shown. A pure aluminum layer 204 is formed on a substrate 202 under the conditions of high pressure and low sputtering power. The pressure is about 0.5 Pa to 4 Pa, with 1.0 Pa as the preferred pressure. The sputtering power is about 0.1 W/cm² to 10 W/cm². Subsequently, an aluminum layer 206 containing nitrogen, such as an aluminum-nitride (AlN) layer or an aluminum-oxide-nitride (AlON) layer, is formed on the pure aluminum layer 204. The thickness of the aluminum layer 206 is about 100 Å to 1000 Å, with a preferred thickness range of 300 Å to 800 Å. The film formation conditions of the aluminum layer 206 are not limited. The pressure for forming the aluminum layer 206 can be 0.3 Pa. An aluminum layer 206 that contains nitrogen formed on the pure aluminum layer 204 can effectively prevent the pure aluminum layer 204 from forming a hillock surface.

Referring to FIG. 3, a schematic view of three aluminum layers formed on a substrate according to a second preferred embodiment of the invention is shown. A first pure aluminum layer 304a is formed on a substrate 302 under high pressure and low sputtering power conditions. The pressure is about 0.5 Pa to 4 Pa, with a preferred pressure of 1.0 Pa. The sputtering power is about 0.1 W/cm² to 10 W/cm². Afterwards, a second pure aluminum layer 304b is formed on the first aluminum layer 304a. An aluminum layer 306 containing nitrogen, such as an aluminum-nitride (AlN) layer or an aluminum-oxide-nitride (AlON) layer, is then formed on the second pure aluminum layer 304b. The thickness of the aluminum layer 306 is about 100 Å to 1000 Å, with a preferred thickness range of 300 Å to 800 Å. The film formation conditions of the aluminum layer 306 are not limited. The pressure to form the aluminum layer 306 can be 0.3 Pa. An aluminum layer 306 containing nitrogen formed on the pure aluminum layer 304b can effectively prevent the pure aluminum layer 304b from forming a hillock surface.

Although two pure aluminum layers are illustrated as an example in the second preferred embodiment, the invention is not limited to having only two pure aluminum layers; more than two pure aluminum layers can be formed, and hillock surfaces can be prevented since the latest deposited pure aluminum layer is covered by an aluminum layer containing nitrogen. In practical applications, the pure aluminum layers can also include other elements, but that will be more costly than using pure aluminum layers.

Furthermore, for multiple pure aluminum layers, it can effectively prevent the formation of hillocks as the pure aluminum layer, which is closer to the substrate, has smaller and less dense crystal particles. However, the invention is not limited to the above condition. This invention is to form an aluminum layer with nitrogen on the pure aluminum layers and the conditions of high pressure and low sputtering power for forming film on the pure aluminum layers is achieved.

A series of experiments on the structure of the aluminum layer of the invention are conducted as follows. Annealing is conducted for one hour at a temperature of 350° C.; the upper surface of the aluminum layer is observed by a scanning electron microscope to detect the presence of hillocks. Experiment results are shown in List 1.

List 1

| The film | The film | | Whether hillocks are |
|---|---|---|---|
| formation | thickness | The film formation | generated after |
| pressure (Pa) | (Å) | power (W/cm²) | annealing |
| 0.3 | 2000 | 6.5 | Generated |
| 4 | 2000 | 6.5 | A few |
| 4 | 2000 | 2 | No |
| 4 | 1000 + 1000 | 2 + 6.5 | No |
| 4 | 1000 + 1000 | 4 + 6.5 | No |

Example 1 (for comparison):

One pure aluminum layer is deposited on the substrate under the pressure 0.3 Pa and the sputtering power (i.e. the film formation power) 6.5 W/cm¹. An aluminum layer containing nitrogen is then formed on the pure aluminum layer. It is then annealed for one hour at a temperature of 350° C.; the upper surface of the aluminum layer is observed by a scanning electron microscope to detect the presence of hillocks. The experiment results show that hillocks will be generated under low pressure and high sputtering power.

Experiment 2 (for comparison):

One pure aluminum layer is deposited on the substrate under the pressure 4 Pa and the sputtering power 6.5 W/cm². An aluminum layer containing nitrogen is then formed on the pure aluminum layer. It is then annealed for one hour at a temperature of 350° C.; the upper surface of the aluminum layer is observed by a scanning electron microscope to detect the presence of hillocks. The experiment results show that a few hillocks will be generated as the pressure is increased but the sputtering power is not lowered.

Experiment 3:

One pure aluminum layer is deposited on the substrate under the pressure 4 Pa and the sputtering power 2.0 W/cm². An aluminum layer with nitrogen is then formed on the pure aluminum layer. It is annealed for an hour at 350° C.; the upper surface of the aluminum layer is observed with a scanning electron microscope to detect the formation of hillocks. The experiment results show that hillock surfaces will be prevented as the pressure is increased and the sputtering power is lowered.

Experiment 4:

A first pure aluminum layer is deposited on the substrate under the pressure 4 Pa and the sputtering power 2.0 W/cm². A second pure aluminum layer is, subsequently, deposited on the first pure aluminum layer under the film formation pressure 4 Pa and the sputtering power 6.5 w/cm². An aluminum layer with nitrogen is then formed on the second pure aluminum layer. After the substrate is annealed for an hour at 350° C., the upper surface of the aluminum layer is observed with a scanning electron microscope to detect the presence of hillocks. The experiment results show that as multiple pure aluminum layers are formed under high pressure and increasing sputtering power, no hillocks are generated.

Experiment 5:

A first pure aluminum layer is deposited on the substrate under the pressure 4 Pa and the sputtering power 4.0 W/cm². A second pure aluminum layer is, subsequently, deposited on the first pure aluminum layer under the film formation pressure 4 Pa and the sputtering power 6.5 w/cm². An aluminum layer with nitrogen is then formed on the second pure aluminum layer. It is annealed for an hour at 350° C.; the upper surface of the aluminum layer is observed with a scanning electron microscope to detect the presence of hillocks. The experiment results show that as multiple pure aluminum layers are formed under high pressure and the first pure aluminum layer is formed under a higher sputtering power than that (2.0 W/cm²) used in experiment 4, no hillocks are generated.

The hillock-free gate layer and method of manufacturing the same according to the invention has the advantages that the cost is lower than a typical process using Mo or Cr, the process is easily conducted, and hillocks that make subsequent layers uneven are not generated.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A hillock-free gate layer, the gate layer comprising:
At least one pure aluminum layer, formed on the substrate; and
an aluminum layer containing nitrogen, formed on the pure aluminum layer, the aluminum layer containing nitrogen;
wherein the aluminum layer containing nitrogen prevents the pure aluminum layer from generating hillocks.

2. The gate layer according to claim 1, wherein the aluminum layer containing nitrogen is an aluminum-nitride (AlN) layer.

3. The gate layer according to claim 1, wherein the aluminum layer containing nitrogen is an aluminum-oxide-nitride (AlON) layer.

4. A method of manufacturing a hillock-free gate layer, for preventing the formation of hillocks, the method comprising the steps of:
(a) forming at least one pure aluminum layer on a substrate under a first pressure and a first sputtering power, wherein the first pressure is in the range of 0.5 Pa to 4 Pa, and the first sputtering power is in the range of 0.1 W/cm² to 10 W/cm²; and
(b) forming an aluminum layer containing nitrogen on the pure aluminum layer under a second pressure and a second sputtering power, wherein the thickness of the aluminum layer containing nitrogen is about 100 to 1000 Å.

5. The method according to claim 4, wherein the first pressure is preferably 1 Pa.

6. The method according to claim 4, wherein the second pressure is 0.3 Pa.

7. The method according to claim 4, wherein the thickness of the aluminum layer containing nitrogen is preferably in the range of about 300 Å to 800 Å.
